(19) United States
(12) Patent Application Publication
(10) Pub. No.: US 2002/0182852 A1
(43) Pub. Date: Dec. 5, 2002

(54) Method for reducing micro-masking defects in trench isolation regions

(75) Inventor: Kailash N. Singh, San Antonio, TX (US)

Correspondence Address: Corporate Patent Counsel, U.S. Philips Corporation, 580 White Plains Road, Tarrytown, NY, 10591, US

(73) Assignee: Koninklijke Philips Electronics N.V.

(21) Appl. No.: 09/849,389

(22) Filed: May 3, 2001

(51) Int. Cl. H01L 21/4763

(52) U.S. Cl. 438/637

(57) ABSTRACT

A method for manufacturing a semiconductor device uses a silicon etch process that minimizes micro-masking defects in shallow trench isolation regions. In an example embodiment, a silicon etch comprising Cl₂, HBr, HeO₂, and N₂ is introduced onto the substrate; the volumetric flow of Cl₂ being in the range of about 60 sccm, the volumetric flow of HBr being in the range of about 150 sccm; and the volumetric flow of HeO₂ being in the range of about 10 sccm and the volumetric flow of N₂ being the range of about 20 sccm, with a pressure maintained at about 60 mT. The silicon etch forms a trench of a predetermined depth.

### FIELD OF INVENTION

The present invention is generally directed to the manufacture of a semiconductor device. In particular, the present invention relates to a process that reduces the formation of silicon etch defects known as micro masking.

### BACKGROUND OF INVENTION

One important stage in the manufacture of semiconductor devices is the formation of isolation areas to electrically separate the active devices or portions thereof, that are closely integrated in the silicon wafer. The particular structure of a given active device can vary between device types, a MOS-type transistor generally includes source and drain regions and a gate electrode that modulates current flowing in a channel between the source and drain regions. Unintended current should not flow between source and drain regions of adjacent MOS-type transistors. However, during the manufacturing process, movement of dopant atoms, for example, of boron, phosphorus, arsenic, or antimony, occurs within the solid silicon of the wafer. This movement is referred to as diffusion. The diffusion process occurs at elevated temperatures where there is a concentration gradient between dopant atoms, external to the silicon wafer and those dopant atoms within the silicon wafer. It is typically employed when forming p-type and n-type regions of a silicon integrated circuit device.

A technique referred to as “trench isolation” has been used to limit unintended current flow among transistors. A particular type of trench isolation is referred to as shallow trench isolation (STI). STI is often used to separate the respective diffusion regions of devices of the same or different polarity type (i.e., p-type versus n-type). The trench regions are formed in the semiconductor substrate by recessing the substrate deeply enough for isolation and refilling with insulating material to provide the isolation among active devices or different well regions.

In a conventional process, a significant problem with STI is that during trench etch defects are formed. These defects are referred to as micro masking. FIG. 1 depicts an area 100 having undergone a conventional silicon etch. The silicon etch is used to form the trench isolation 110. Micro masking defects 120 remain. Consequently, device quality and reliability may be impaired in that the quality of the trench is compromised.

### SUMMARY OF INVENTION

In a conventional trench etch process (silicon etch) removal of native oxide is often considered the only factor for micro masking. A method for trench etching uses very low pressure (about 10 mT to about 30 ml) in a plasma etch apparatus, such as a LAM 9400SE. The etch results in blocked silicon etch defects.

Micro masking defects are formed due to the blocking of silicon etch owing to incomplete removal of native oxide and the lack of an isotropic component in the etch chemistry.

Accordingly, a need exists for a shallow trench isolation process that minimizes the formation of defects as the process technology approaches fractional microns.

The present invention is exemplified in a number of implementations, one of which is summarized below. The invention uses the finding that adjusting the pressure and flow of chlorine in the etch process has a pronounced effect on the generation of micro masking defects. In one example embodiment a method for manufacturing a semiconductor device comprises forming a least one trench isolation region on a silicon substrate. Forming the trench isolation comprises defining a trench pattern through lithography, etching the trench pattern to a predetermined depth in the silicon substrate with a silicon etch. The silicon etch comprises introducing a process gas of Cl₂, HBr, HeO₂, N₂ onto the substrate. The volumetric flow of Cl₂ is in the range of about 40 sccm to about 80 sccm. The volumetric flow of HBr is in the range of about 140 sccm to about 160 sccm. The volumetric flow of HeO₂ is in the range of about 8 sccm to 12 sccm and the volumetric flow of N₂ is in the range of about 18 sccm to about 25 sccm. The trench pattern is etched by generating a plasma to form an etch gas from the process gas.

The above summary of the present invention is not intended to represent each disclosed embodiment, or every aspect, of the present invention. Other aspects and example embodiments are provided in the figures and the detailed description that follows.

### BRIEF DESCRIPTION OF THE DRAWINGS

The invention may be more completely understood in consideration of the following detailed description of various embodiments of the invention in connection with the accompanying drawings, in which:

FIG. 1 illustrates the micro masking defects of a prior art process;

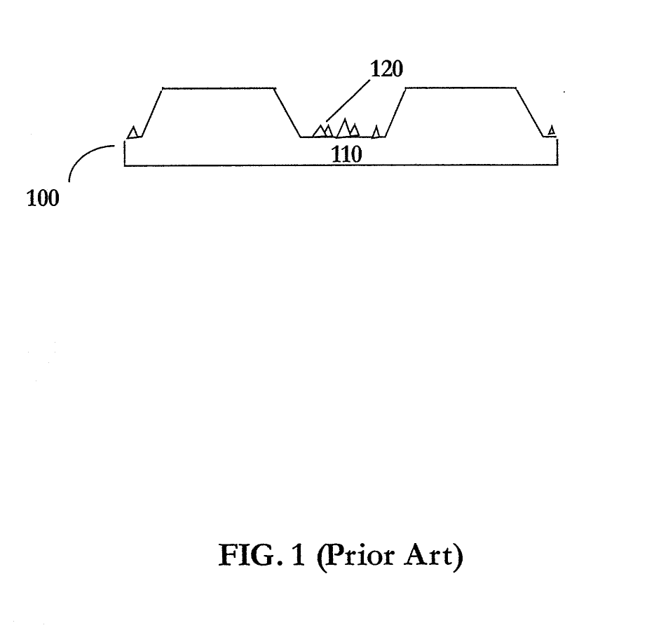

FIG. 2 depicts in cross-section the structure that is etched according to an embodiment of the present invention; and

FIG. 3 outlines the series of steps of the trench etch as performed in FIG. 2.

While the invention is susceptible to various modifications and alternative forms, specific embodiments thereof have been shown by way of example in the drawings and will herein be described in detail. It should be understood, however, that it is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

The present invention has been found to be useful and advantageous in connection with an STI (shallow trench isolation) process used in the manufacture of MOS-type transistors. The present invention has been found to be particularly useful in reducing the incidence of micro masking defects during silicon etch. The formation of shallow trench isolation may be further understood by referring to patent application (Ser. No. 09/411,758) titled, “Method for a Consistent Shallow Trench Etch Profile” of T. Zheng et al, filed on Oct. 4, 1999 incorporated by reference, herein.

Typically, the trench isolation process includes forming shallow trenches in the silicon which ultimately are filled in with oxide or another suitable dielectric. In the discussion that follows, a MOS structure is used to describe an example implementation of the invention. However, the invention is not necessarily limited to MOS. It may be applied to alternate technologies such as bipolar, silicon on substrate, gallium arsenide, and combinations thereof.

An example process deposits, on the silicon wafer, a passivation dielectric, usually silicon dioxide. Following the passivation dielectric deposition, a nitride deposition is applied forming a nitride hard mask. An additional dielectric is deposited on the nitride hard mask layer. This additional dielectric may be a silicon-oxynitride, SiₓO_{y}N_{z} or a silicon-rich oxide, SiOₓ. The passivation dielectric, the nitride hard mask, and additional layer form a dielectric stack. The dielectric stack structure assists in defining the STI. Photolithography masks areas to etch. A dielectric stack etch removes unwanted dielectric and proceeds until silicon is reached. Stripping of the photo mask prepares the silicon wafer for the plasma etch of the silicon trenches.

According to an embodiment of the present invention, the substrate undergoes silicon trench etch, the dielectric stack protecting the regions that ultimately define the active transistor areas. After the silicon trench etch, the trenches are filled with a dielectric, usually a HDP (high-density plasma) oxide. Having defined the trench isolation, the wafer undergoes subsequent processing to further define the active transistor areas that comprise the circuits on a given device. The silicon etch according to the present invention reduces the incidence of micro masking.

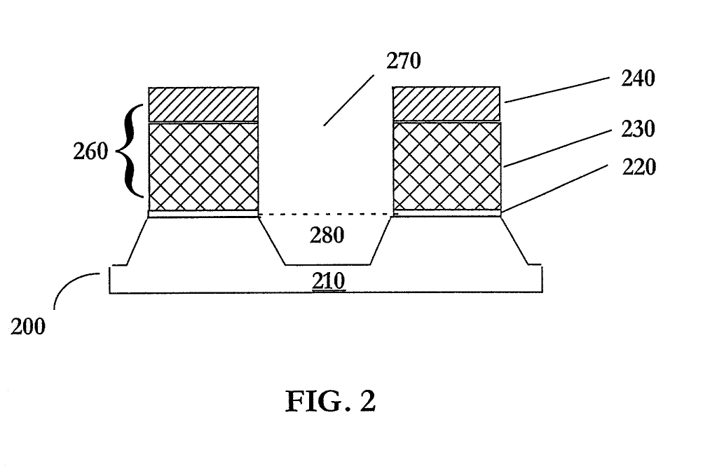

Refer to FIG. 2. A structure 200, has been etched by the process according to the present invention. The dielectric stack 260 is comprised of a passivation dielectric, usually thin oxide 220. A nitride layer 230 covers the thin oxide 220. On the nitride is the additional dielectric 240. The dielectric stack 260 has been etched to the silicon layer 210.

The silicon trench etch according to an embodiment of the present invention defines the STI region 280.

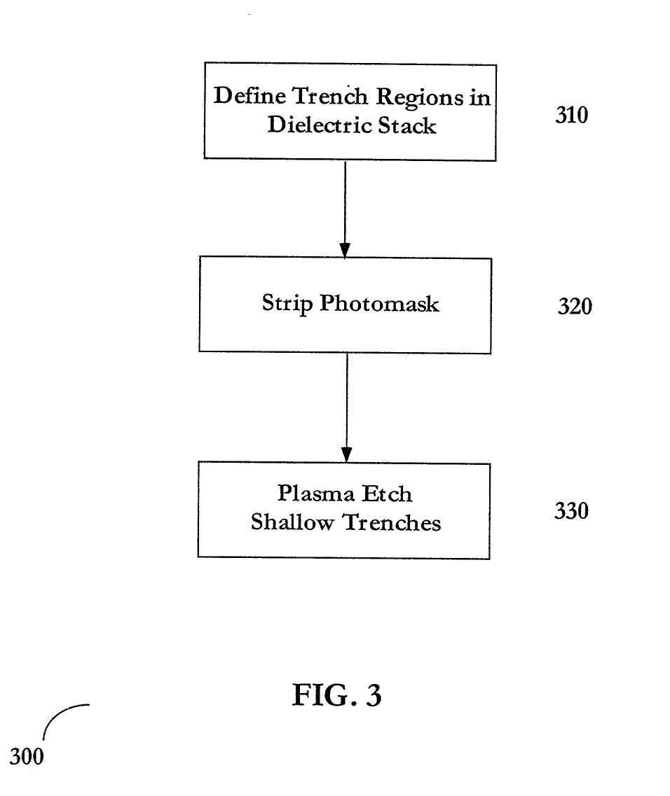

Refer to FIG. 3. The process 300 is accomplished by defining 310 trench regions in the dielectric stack 260, the trench regions have been defined by photolithography. The photomask is stripped off in Step 320. The remaining dielectric stack acts as a hardmask to the plasma etch 330 of the silicon trenches. An example process according to the present invention is outlined in Table 1.

Refer to Table 1. The “Shallow Silicon Trench Etch” process is used to etch the trench regions of the semiconductor device. The Shallow Silicon Trench Etch uses a Lam Research Corporation Model TCP 9400SE plasma etch apparatus. In the etch apparatus, the silicon etch process, Stage 01 begins with loading wafers into an etching chamber; the chamber is pumped down to vacuum conditions and CF₄ is introduced. Stage 02 is for removing the native oxide that grows on bare silicon upon exposure to the air. This stage would not be needed in a “cluster” tool there the wafer is kept under vacuum conditions between a dielectric stack etch and trench etch. Such a tool may comprise multiple etch chambers or processes.

TABLE 1
Shallow Silicon Trench Etch

| | Gas | Clean Si | Gas | Trench | Pump | |
|---|---|---|---|---|---|---|
| Shallow Silicon | stability | surface | stability | etch | chamber | End |
| Trench Etch | Stage 01 | Stage 02 | Stage 03 | Stage 04 | Stage 05 | Stage 06 |
| Pressure (mTorr) | 10 | 10 | 60 | 60 | 0 | 0 |
| RF-Top (W) | 0 | 250 | 0 | 250 | 0 | 0 |
| RF-Bottom (W) | 0 | 65 | 0 | 80 | 0 | 0 |
| Gap (cm) | 8.1 | 8.1 | 8.1 | 8.1 | 8.1 | 8.1 |
| Cl2 (sccm) | 0 | 0 | 60 | 60 | 0 | 0 |
| HBr (sccm) | 0 | 0 | 150 | 150 | 0 | 0 |
| 80% He—O2 (sccm) | 0 | 0 | 10 | 10 | 0 | 0 |
| CF4 (sccm) | 100 | 100 | 0 | 0 | 0 | 0 |
| N2 (sccm) | 0 | 0 | 23 | 23 | 0 | 0 |
| He clamp (Torr) | 8 | 8 | 8 | 8 | 0 | 0 |
| Completion | Stabl | Time | Stabl | Time | Time | End |
| Time (sec) | 30 | 10 | 30 | 100** | 7 | 0 |

| Temperatures | ° C. |
|---|---|
| Bottom Electrode | 60 |
| Chamber | 60 |

**= 100 sec is typical but is adjusted to meet the required trench

Going to Stage 03, the species of etch gases, Cl₂ and HBr, HeO₂ and N₂ are introduced into the chamber at flow rates of about 60 sccm, about 150 sccm, about 10 sccm, and about 20 sccm, respectively. Note that HeO₂ is a mixture of 80% He and 20% O₂. Chamber pressure is held at about 30 mT. Bottom electrode temperature is set to about 60° C. The gas flows require approximately 30 seconds to stabilize.

Acting as a hard mask, silicon oxynitride/silicon nitride/silicon dioxide of the dielectric stack protect regions of silicon not undergoing trench etch. At Stage 04, exposed silicon regions, for about 80 seconds to about 120 seconds at a “Top RF” power of about 250 watts (W) and about 80 watts “Bottom-RF” power, the wafers are plasma etched with the Cl₂, HBr, HeO₂, and N₂ combination.

The process completes Stage 04 when the etch gases are evacuated and RF power is switched off. The system pumps down to vacuum during Stages 05-06. Wafers are removed from the silicon etch apparatus for the deposition of an oxide to fill in the trench. The wafers then undergo further processing.

Although the above example embodiment etches the silicon while mining defects it should be noted that a range of process parameters may be used. In another example embodiment according to the present invention, depending upon specific process conditions, a pressure in the range of about 40 mT to about 80 mT is desirable for the constituent process gases. The constituent process gases are introduced at flow rates of about 40 sccm to 60 sccm for Cl₂, about 8 sccm to about 15 sccm for He—O₂, about 18 sccm to about 25 sccm for N₂ and about 140 sccm to about 160 sccm for HBr. In yet another example embodiment, the pressure may be in the range of about 50 to about 70 mT.

While the present invention has been described with reference to several particular example embodiments, those skilled in the art will recognize that many changes may be made thereto without departing from the spirit and scope of the present invention, which is set forth in the following claims.

What is claimed:

1. A method for manufacturing a semiconductor device comprising:
forming at least one trench isolation region on a silicon substrate wherein the forming of the trench isolation comprises,
defining a trench pattern through photolithography;
etching the trench pattern to a predetermined depth in the silicon substrate with a silicon etch, wherein the silicon etch comprises;
introducing a process gas comprising Cl₂, HBr, HeO₂, N₂ onto the substrate, the volumetric flow of Cl₂ being in the range of about 40 sccm to about 80 sccm, the volumetric flow of HBr being in the range of about 140 sccm to about 160 sccm; and the volumetric flow of HeO₂ being in the range of about 8 sccm to about 15 sccm and the volumetric flow of N₂ being in the range of about 18 sccm to about 25 sccm; and
generating a plasma to form an etch gas from the process gas; and
etching the trench pattern with the etch gas.

2. The method of claim 1 wherein, a pressure in the range of about 40 mT to about 80 mT is maintained.

3. The method of claim 1 wherein, the volumetric flow of Cl₂ is in the range of about 50 sccm to about 70 sccm.

4. The method of claim 1 wherein, the volumetric flow of Cl₂ is in the range of about 55 sccm to about 65 sccm.

5. The method of claim 1 wherein, a pressure in the range of about 50 mT to about 70 mT is maintained.

6. The method of claim 1 wherein, a pressure in the range of about 55 mT to about 65 mT is maintained.

7. A method of etching silicon, the method comprising:
introducing a first etch comprising CF₄ at a volumetric flow rate of about 100 mT at a pressure of about 10 mT removing native oxidation on the silicon for about 10 seconds;
introducing a second etch comprising Cl₂, HBr, HeO₂, N₂ onto the substrate, the volumetric flow of Cl₂ being in the range of about 60 sccm, the volumetric flow of HBr being in the range of about 150 sccm; and the volumetric flow of HeO₂ being in the range of about 10 sccm and the volumetric flow of N₂ being in the range of about 20 sccm, with a pressure maintained in the range of about 50 to about 70 mT, removing silicon.

8. The method of claim 7 wherein the silicon is removed at predetermined depth in the range of about 2000 Å to about 5000 Å.

9. A semiconductor device manufactured with a method comprising:
defining a pattern through photolithography;
etching the pattern to a predetermined depth in the silicon substrate with a silicon etch, wherein the silicon etch comprises;
introducing a process gas comprising Cl₂, HBr, HeO₂, N₂ onto the substrate, the volumetric flow of Cl₂ being in the range of about 40 sccm to about 60 sccm, the volumetric flow of HBr being in the range of about 140 sccm to about 160 sccm; and the volumetric flow of HeO₂ being in the range of about 8 sccm to about 12 sccm and the volumetric flow of N₂ being in the range of about 18 sccm to about 25 sccm; and
generating a plasma to form an etch gas from the process gas; and
etching the pattern with the etch gas.

10. The semiconductor device manufactured by the method of claim 9 wherein, a pressure is maintained in the range of about 50 mT to about 70 mT.

11. The semiconductor device manufactured by the method of claim 9 wherein, the pressure is maintained in the range of about 55 mT to about 65 mT.

12. The semiconductor device manufactured by the method of claim 9 wherein the predetermined depth is in the range of about 2000 Å to about 5000 Å.
